(19) United States
(12) Patent Application Publication
(10) Pub. No.: US 2005/0040546 A1
(43) Pub. Date: Feb. 24, 2005

(54) Radiation hardened microelectronic device

(76) Inventors: Joseph D. Cuchiaro, Colorado Springs, CO (US); Gary S. Tompa, Belle Mead, NJ (US)

Correspondence Address: DOCKET ADMINISTRATOR;LOWENSTEIN SANDLER PC, 65 Livingston Avenue, Roseland, NJ, 07068-1791, US

(21) Appl. No.: 10/839,040

(22) Filed: May 5, 2004

Related U.S. Application Data
(60) Provisional application No. 60/469,245, filed on May 12, 2003.

(51) Int. Cl. H01L 23/48

(52) U.S. Cl. 257/903

(57) ABSTRACT

A “hardened by design” approach is described that identifies a radiation-sensitive region of a microelectronic device, constructing wells in the region with low volume, constructing a conductive path in the region so as to shield sensitive region and constructing the conductive path from low resistance material. An exemplary SRAM cell uses these principles and may be divided and interleaved in order to further radiation harden the device.

### CROSS REFERENCE TO RELATED APPLICATIONS

This patent application is related to and claims the benefit of Provisional U.S. Patent Application No. 60/469,245, filed May 12, 2003, entitled “Hardened SRAM” by Gary Tompa and Joseph Cuchiaro, and is incorporated by reference herein in its entirety.

### FIELD OF THE INVENTION

This invention is related to the field of radiation-hardened microelectronic devices, and, more specifically, to microelectronic devices that employ a combination of lower conductive resistivity, additional metal layers and low volume wells to provide radiation hardening using modern microelectronic fabrication techniques. These hardening techniques are described herein in terms of a radiation-hardened SRAM.

### BACKGROUND OF THE INVENTION

It is well known in the art that components of microelectronic semiconductor devices, including, but not limited to, transistors, diodes, etc. can change state due to radiation strikes at sensitive nodes. Many techniques have been developed over the years to resist these effects. These techniques are generally known in the art as “hardening.”

FIG. 1 illustrates a schematic drawing of a 6-transistor, single-bit SRAM cell 100 illustrating how a bit changes state following a particle strike in a sensitive node. There are two gating n-channel transistors 102 and 104 at either end of SRAM cell 100. Further, a first node 106 of SRAM cell 100 includes a p-channel transistor 108 comprising a gate 110 source 112 and drain 114, as is known in the art. First node 106 of SRAM cell 100 also includes an n-channel transistor 116 comprising a gate 118 source 120 and drain 122, as is also known in the art.

A second node 130 of SRAM cell 100 includes a p-channel transistor 132 comprising gate 134, source 136 and drain 138. Second node 130 also includes a n-channel transistor 140 comprising gate 142, source 144 and drain 148. Gates 110 and 118 are connected together by line 150, which is also connected to gating transistor 104. Likewise, second node 130 transistors gates 134 and 142 are connected via line 152 to gating transistor 102. Voltage is applied at line 154 and ground is at 156.

In FIG. 1, first node 106 is at a “0” prior to a particle strike that generates ions or a charge. A particle, following path 160, strikes at point 162. Following the strike, a charge is generated or deposited at point 162 raising line 150 so that gates 110 and 118 of transistors 108 and 116, respectively, are raised. If the strike generates sufficient charge, then the n-channel 116 transistor turns on and the p-channel transistor 116 turns off, pulling first node 106 to “1”. If sufficient charge is generated, then the SRAM cell locks in the new “data.” This process continues, with the first node 106 now feeding back to gates 134 and 142 of n-channel transistor 140 and p-channel transistors 132, respectively, on second node 130. Hence it may be seen in this illustration that even redundant node may not be sufficient to maintain a state in an SRAM cell.

One structure that is known in the art that helps harden a cell is to use a redundant cell, known in the art as a “DICE” cell. A DICE SRAM cell is illustrated in FIG. 2. FIG. 2 includes four nodes (and the circuitry controlling the node), 202, 204, 206 and 208, which are in contrast with the two nodes of FIG. 1. The additional nodes aid in maintaining the stability of the cell by providing feedback than is available in the cell of FIG. 1.

A DICE cell, however, requires more transistors and hence more die space. As electronic devices shrink, such cells take more and more space on the die. Further, as a DICE cell shrinks to the level of 0.25 μm, the wells of the transistors become closer together. Such well proximity results in the DICE cell being vulnerable to a single particle strike because multiple nodes react to the event, causing a bit flip in the same manner as outlined above.

Thus, there is a need in the art for an inexpensive, effective hardening process that is compatible with today's processing techniques and size capabilities.

### SUMMARY OF THE INVENTION

This problem is solved and a technical advance is achieved in the art by a system and method that hardens microelectronic structures. A method according to this invention radiation hardens a microelectronic device by identifying a radiation sensitive region of the microelectronic device, constructing a well having a low volume in the sensitive region, constructing a conductive path within the region so as to shield the sensitive region and constructing the conductive path from low resistance material. Further, the conductive path may be routed according to relaxed design rules and may also be routed through one or more of a plurality of layers.

An apparatus in accordance with this invention provides a low volume well and a conductive path comprising low resistance material adjacent to and shielding the low volume well. There may be a plurality of low volume wells and a plurality of conductive paths shielding the plurality of low volume wells. The radiation hardened structure may comprise, but is not limited, to a diode, transistor, laser, light emitting diode, oscillator and memory. The conductive path may be a metal, metal compound, multi-layer metal, conductive organic or a conductive oxide material.

This invention further includes a radiation hardened SRAM cell comprising a first bistate node connected to a bit line via a first selector and a second selector. The SRAM cell also includes a second bistate node connected to a not bit line via a third selector and a fourth selector. There is a first circuit arrange between the first node and the second node configured to maintain the second node in an opposite state of the first node and a second circuit arranged between the second node and the first node configured to maintain the first node in the opposite state of the second node. Advantageously, the first selector and the third selector are selected by not word signals. Further advantageously, the first bistate node and the second bistate node are spatially separated by at least the width of another node. The SRAM cell may be a plurality of SRAM cells that may be interleaved with each other.

Further, this invention includes a radiation-hardened SRAM comprising a plurality of interleaved bit cells. Each bit cell comprises a first bistate node connected to a bit line via a first selector and a second selector, a second bistate node connected to a not bit line via a third selector and a fourth selector, a first circuit arranged between the first node and the second node configured to maintain the second node in an opposite state of the first node and the second circuit arranged between the second node and the first node configured to maintain the first node in an opposite state of the second node. In accordance with this structure, pairs of the adjacent bit cells may be interleaved or the interleaving may be at a word level.

### BRIEF DESCRIPTION OF THE DRAWINGS

A more complete understanding of this invention may be obtained from a study of this specification taken in conjunction with the drawings, in which:

FIG. 1 is a block diagram of a prior art SRAM cell illustrating a single energetic particle causing a bit flip;

FIG. 2 is a block diagram of a prior art DICE cell;

FIG. 3 is a top view block diagram of a transistor have a hardened by design construction in accordance with an aspect of this invention;

FIG. 4 is a cross-sectional view of the transistor of FIG. 3 taken along line A-A;

FIG. 5 is a graph comparing the relative volumes of a conventional well and a retrograde well;

FIG. 6 is an exemplary SRAM bit cell in accordance with another aspect of this invention;

FIG. 7 illustrates an exemplary SRAM using an interleave structure of the SRAM bit cell of FIG. 6 and;

FIG. 8 is a further exemplary SRAM using an interleave structure of an SRAM comprising SRAM bit cells of FIG. 6.

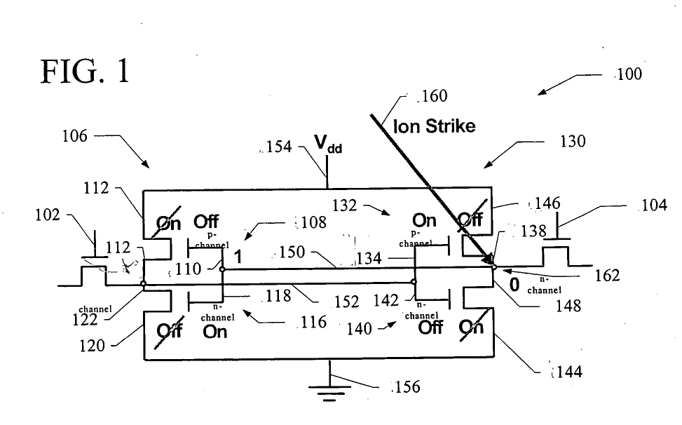

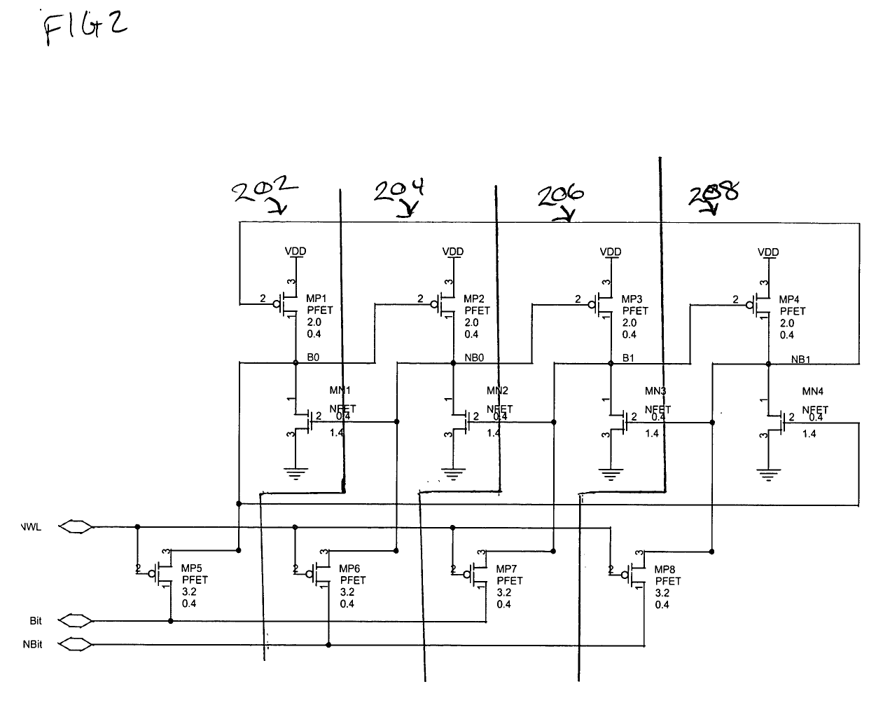

### DETAILED DESCRIPTION

This invention introduces the concept of “hardened by design”. According to this concept, a radiation-hardened microelectronic device may be made using three basic principles: low resistance conductive areas, additional metal layers and low volume fabrication (retrograde) wells. Using these three principles and current scaling factors, potentially harder devices may be made from a prompt dose standpoint.

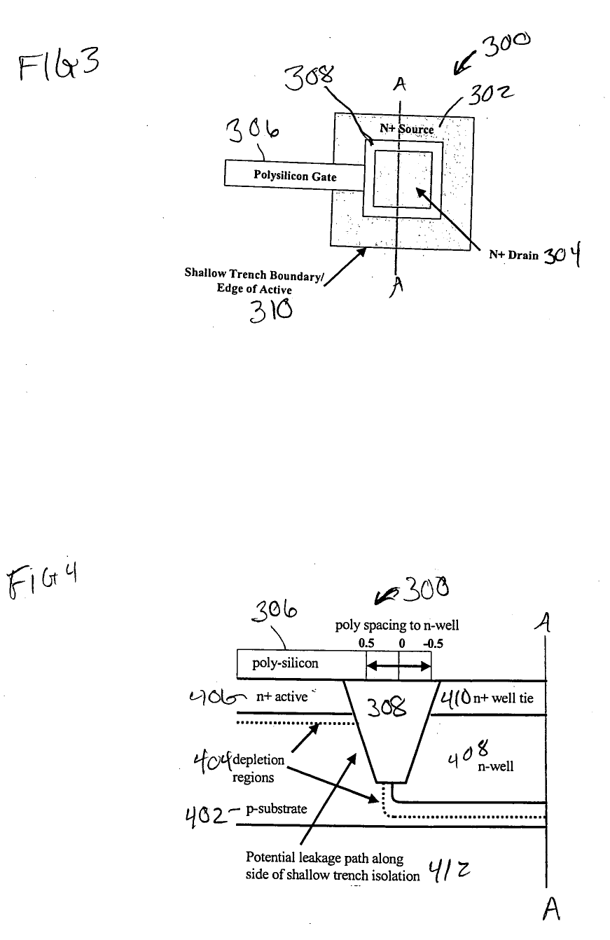

Turning now to FIG. 3, an exemplary electronic device is shown generally at 300. Microelectronic device 300 in this exemplary embodiment comprises an N-P-N transistor. n source material 302 surrounds an N+ drain 304. A polysilicon gate 306 is attached to a dielectric wall 308. There is a shallow trench boundary on the edge of the active region 310.

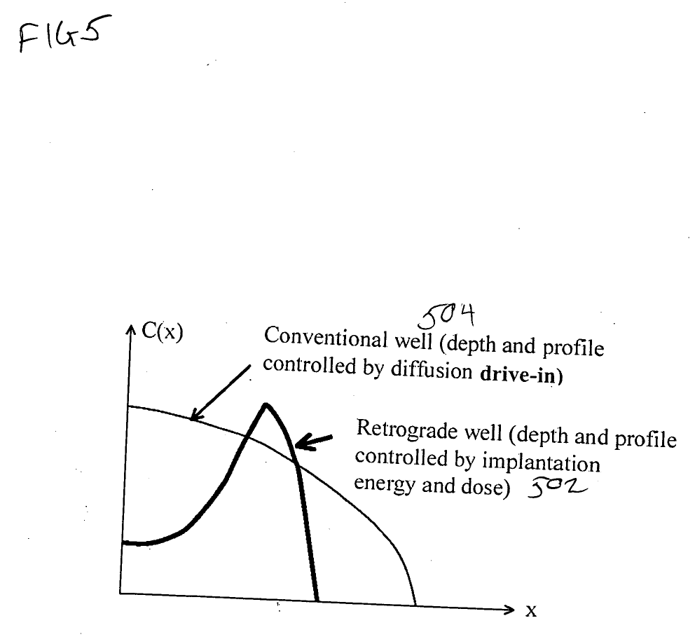

Turning now to FIG. 4, a cross-sectional view of the transistor 300 of FIG. 3 is shown, taken along Line A-A. Polysilicon gate 306 is disposed over of dielectric 308. This transistor is fabricated on a P substrate 402, with depletion regions 404. The N+active region 406 is beneath the polysilicon gate 304.

Significantly, an N-well 408 is shown adjacent to polysilicon dielectric 308. N-well tie 410 lies on top of N-well 408. In this exemplary embodiment of this invention, N-well 408 comprises a retrograde well. A low resistance, conductive path is shown at 307 and 308 protecting the sensitive region.

Turning now to FIG. 5, a comparison is shown between the volume of a retrograde well 504 and the volume of a conventional well 502. The depth and profile of a retrograde well 502 bare controlled by implantation energy and dose. A conventional well 504 depth and profile are controlled by diffusion drive-in. Specifically illustrated in FIG. 5 is that the volume of retrograde well 502 is smaller than the volume of conventional well 504, thus providing a smaller area for a radiation strike.

While this invention is shown in terms of a transistor 300, one skilled in the art will understand how to construct other structures using this hardened by design approach. Examples include, but are not limited to, diodes, lasers, light emitting diodes, oscillators, memory (e.g., SRAM, DRAM). The conductive path 306 comprises a low resistance material in this exemplary embodiment. One skilled in the art will realize that the low resistance material may comprise a metallic material (including, but not limited to, copper, tungsten, aluminum, platinum and gold), a metal compound material (including, but not limited to, titanium nitrate, tantalum nitrate, niobium nitrate and titanium tungsten), a multi-layer metal, a conductive organic or a conductive oxide (including, but not limited to, iridium oxide, zinc oxide, indium tin oxide, strontium ruthenate and lanthanum strontium cobalt oxide).

Furthermore, one small area of a microelectronic device may be hardened by hardened by design techniques, or an entire microelectronic device may be hardened by hardened by design techniques. Thus, there may be many structures having low volume wells and conducted paths that shield this sensitive region made from low resistance material. One skilled in the art will appreciate how to apply these hardened by design principles for specific design tasks after studying this specification.

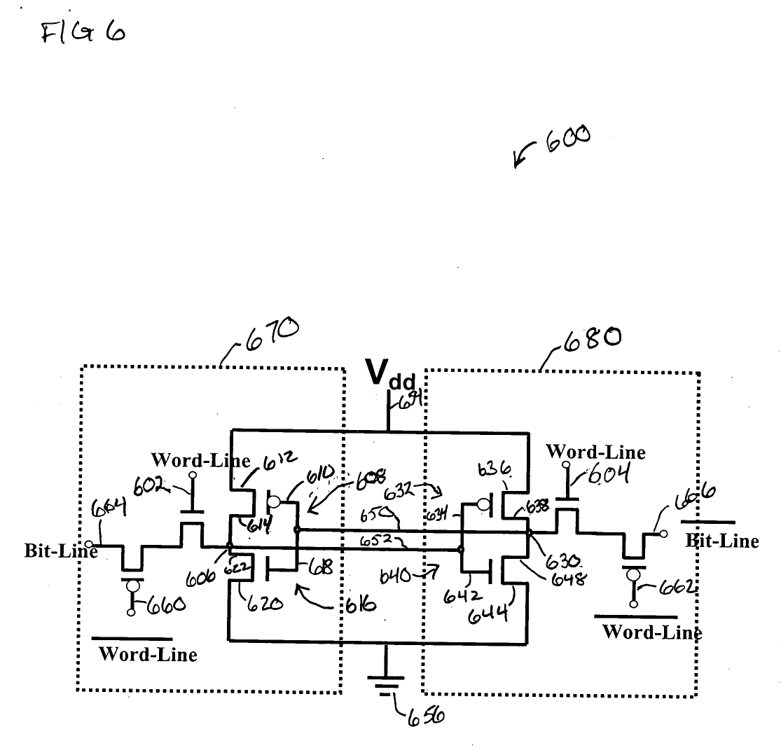

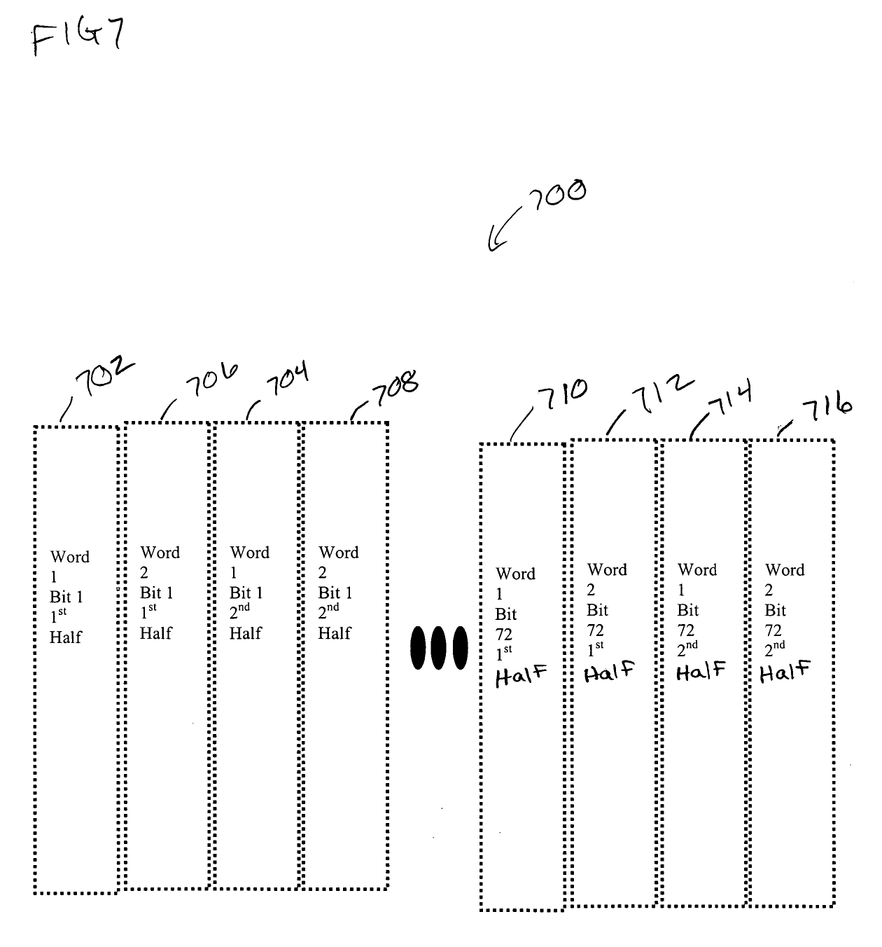

Turning now to FIG. 6, a radiation hardened SRAM cell according to another aspect of this invention is shown, generally at 600. There are two n-channel transistors 602 and 604 at either end of SRAM 100. 602 and 604 are responsive to the word line being active. Further, a first bistate node 606 of SRAM cell 100 includes a circuit comprising a p channel transistor 608, which in turn comprises a gate 610, source 612 and drain 614 bistate. First node 606 of SRAM 100 also includes an n channel transistor 616 comprising n gate 618, source 620 and drain 622.

A second bistate node 630 of SRAM cell 600 includes a p-channel transistor 632 comprising gate 634, source 636 and drain 638. Second node 630 also includes an n channel transistor 640 comprising gate 642, source 644 and drain 648. Gates 610 and 618 are connected together by line 650, which is also connected to gating transistor 604. Likewise, second bistate node 630 transistors gates 634 and 642 are connected via line 652 to gating transistor 602. Voltage is applied at line 654 and ground is at 656.

Further, in accordance with an exemplary embodiment of this invention, there are two additional transistors 660 and 662 which are active when the not word signal is present. Transistor 660 is connected to bit line 664 and transistor 662 is connected to not bit line 666.

Further, in accordance with another aspect of this invention, SRAM cell 600 is divided into two portions. A first portion is in box 670 and a second portion is in box 680. First portion 670 includes first bistate node 606 and its supporting circuitry and second portion 680 includes second bistate node 630 and its supporting circuitry. Boxes 670 and 680 advantageously are separated in space so that a radiation strike at one node is less likely to affect the other node. Further, all components of SRAM cell 600 are constructed using hardened by design techniques, as described above.

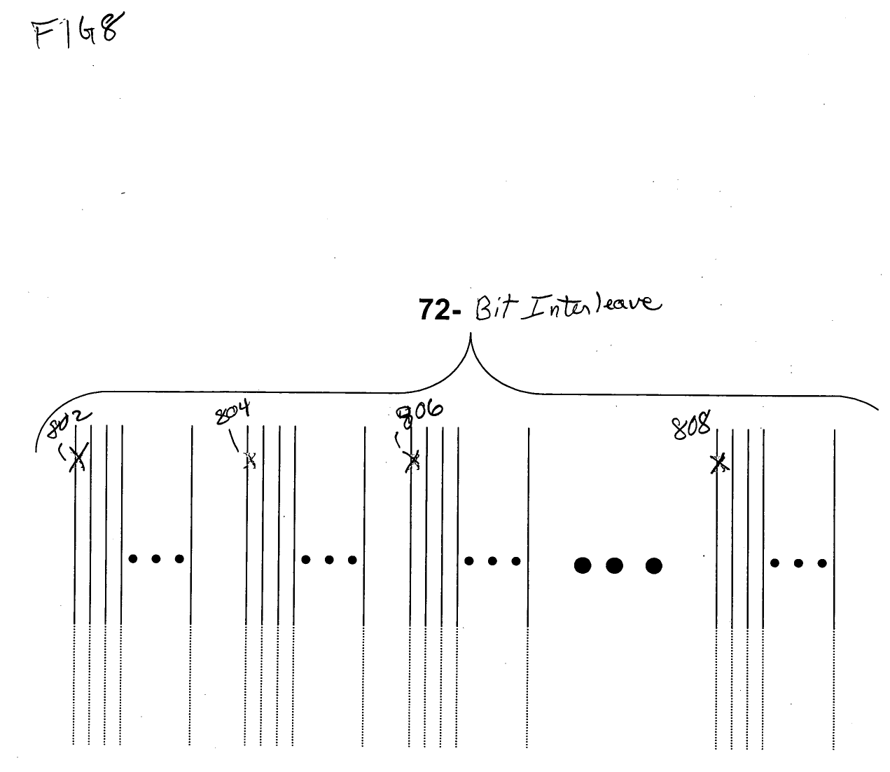

Turning now to FIG. 7 a first bit-half interleaving pattern is described in connection with an SRAM constructed of cells in accordance with FIG. 6. In FIG. 7, there are two 72 bit words interleaved. In this exemplary embodiment, word 1, bit 1, the first half 702 (corresponding to box 670 of FIG. 6) is separated from word 1, bit 1, second half 704 (which corresponds to box 680 of bit 6) by word 2, bit 1, first half 706. Word 2, bit 1, second half 708 is adjacent to word 1, bit 1, second half 704. Such alternate half interweaving continues through word 1, bit 71, first half 710 which is adjacent to word 2, bit 71, first half 712. Word 1, bit 72 second half 714 is next and is between word 2, bit 72, first half 712 and word 2, bit 72 second half 716.

Turning now to FIG. 8 bit-half interleaving for a further 72 bit word is illustrated in connection with a further SRAM constructed of cells in accordance with FIG. 6. In this exemplary embodiment, a first portion of a first bit, shown at 802 is spaced from a second half of the bit shown at 804, by eight other bit halves. Such interleaving could also comprise spacing as shown with first half of bit 806 separated by n bits from second half of the same bit 808.

It is understood that the above-described embodiment is merely illustrative of the present invention and that many variations of the above-described embodiment can be devised by one skilled in the art without departing from the scope of this invention. Further, while the example is described in terms of an Si-based device, the same hardening may be carried out in any semiconductor material system. It is therefore intended that such variations be included within the scope of the following claims and their equivalents.

1. A method for radiation hardening of a microelectronic device comprising:
identifying a radiation sensitive region of the microelectronic device;
constructing a well having a low volume in the sensitive region;
routing a conductive path within the region so as to shield the sensitive region; and
constructing the conductive path from low resistance material.

2. A method in accordance with claim 1 wherein constructing a well having low volume in the sensitive region comprises constructing a plurality of wells having low volume in the sensitive region.

3. A method in accordance with claim 1 wherein constructing a well having low volume in the sensitive region comprises constructing all wells having low volume in the sensitive region.

4. A method in accordance with claim 1 wherein the conductive path is routed according to relaxed design rules.

5. A method in accordance with claim 1 wherein the microelectronic device comprises a plurality of layers, and wherein routing the conductive path comprises routing the conductive path through one or more of the plurality of layers.

6. A method in accordance with claim 1 wherein constructing the conductive path from a low resistance material comprises constructing the conductive path from a low resistance and low impedance material.

7. A method in accordance with claim 1 wherein constructing the conductive path from a low resistance material comprises constructing the conductive path from a metallic material.

8. A method in accordance with claim 7 wherein constructing the conductive path from a metallic material comprises constructing the conductive path from the group consisting of copper, tungsten, aluminum, platinum and gold.

9. A method in accordance with claim 1 wherein constructing the conductive path from a low resistance material comprises constructing the conductive path from a metal compound material.

10. A method in accordance with claim 9 wherein constructing the conductive path from a metal compound material comprises constructing the conductive path from the group consisting of titanium nitride, tantalum nitride, niobium nitride, and titanium tungsten.

11. A method in accordance with claim 1 wherein constructing the conductive path comprises constructing the conductive path from a conductive oxide.

12. A method in accordance with claim 11 wherein constructing the conductive path from a conductive oxide comprises constructing the conductive path selected from the group consisting of iridium oxide, zinc oxide, indium tin oxide and lanthanum strontium oxide.

13. A method in accordance with claim 1 wherein constructing the well having low volume in the sensitive region comprises constructing the well in the sensitive region as a retrograde well.

14. A method in accordance with claim 1 wherein constructing the well having low volume in the sensitive region comprises controlling implantation energy and dose.

15. A method in accordance with claim 1 further including:
providing a semiconductor substrate.

16. A radiation-hardened structure on a microelectronic device comprising:
a low volume well; and
a conductive path comprising low resistance material adjacent to and shielding the low volume well.

17. A radiation-hardened structure in accordance with claim 16 wherein the conductive path comprises a plurality of conductive paths adjacent to and shielding the low volume well.

18. A radiation-hardened structure in accordance with claim 16 wherein the low volume well comprises a plurality of low volume wells.

19. A radiation-hardened structure in accordance with claim 16 wherein the low volume well comprises a plurality of low volume wells and the conductive path comprises a plurality of conductive paths adjacent to and shielding the plurality of low volume wells.

20. A radiation-hardened structure in accordance with claim 16 wherein said radiation-hardened structure comprises a diode.

21. A radiation-hardened structure in accordance with claim 16 wherein said radiation-hardened structure comprises a transistor.

22. A radiation-hardened structure in accordance with claim 16 wherein said radiation-hardened structure comprises a laser.

23. A radiation-hardened structure in accordance with claim 16 wherein said radiation-hardened structure comprises a light emitting diode.

24. A radiation-hardened structure in accordance with claim 16 wherein said radiation-hardened structure comprises an oscillator.

25. A radiation-hardened structure in accordance with claim 16 wherein the radiation-hardened structure comprises a memory.

26. A radiation-hardened structure in accordance with claim 25 wherein the memory comprises an SRAM.

27. A radiation-hardened structure in accordance with claim 25 wherein the memory comprises a DRAM.

24. A radiation-hardened structure in accordance with claim 16 wherein the conductive path comprises a low resistance and low impedance material.

25. A radiation-hardened structure in accordance with claim 16 wherein the conductive path comprises a metallic material.

26. A radiation-hardened structure in accordance with claim 25 wherein the metallic material is selected from the group consisting of copper, tungsten, aluminum, platinum and gold.

27. A radiation-hardened structure in accordance with claim 16 wherein the conductive path comprises a metal compound material.

28. A radiation-hardened structure in accordance with claim 27 wherein the metal compound material is selected from the group consisting of titanium nitride, tantalum nitride, niobium nitride, and titanium tungsten.

29. A radiation-hardened structure in accordance with claim 16 wherein the conductive path comprises a conductive oxide.

30. A radiation-hardened structure in accordance with claim 29 wherein the conductive oxide is selected from the group consisting of iridium oxide, zinc oxide, indium tin oxide and lanthanum strontium oxide.

31. A radiation-hardened SRAM cell comprising:
a first bi-state node connected to a bit line via a first selector and a second selector;
a second bi-state node connected to a not bit line via a third selector and a fourth selector;
a first circuit arranged between the first node and the second node configured to maintain the second node in an opposite state of the first node; and
a second circuit arranged between the second node and the first node configured to maintain the first node in an opposite state of the second node.

32. A radiation-hardened SRAM cell in accordance with claim 31 wherein the first selector and the third selector are selected by a not-word signal.

33. A radiation-hardened SRAM cell in accordance with claim 31 wherein the second selector and the fourth selector are selected by a word signal.

34. A radiation-hardened SRAM cell in accordance with claim 31 wherein the first bi-state node are spatially separated from the second bi-state node by at least the width of a node.

35. A radiation-hardened SRAM cell in accordance with claim 31 wherein the first bi-state node, the bit line, the first selector, the second selector and the first circuit are spatially separated from the second bi-state node, the bit line, the first selector, the second selector and the second circuit by at least the width of a node.

36. A radiation-hardened SRAM cell in accordance with claim 31 further comprising a plurality of radiation-hardened SRAM cells, wherein the first bi-state node of each of the plurality of radiation-hardened SRAM cells is interleaved with each other.

37. A radiation-hardened SRAM cell in accordance with claim 31 further comprising a plurality of radiation-hardened SRAM cells, wherein the second bi-state node of each of the plurality of radiation-hardened SRAM cells is interleaved with each other.

38. A radiation-hardened SRAM cell in accordance with claim 31 further comprising a plurality of radiation-hardened SRAM cells, wherein the first bi-state node of each of the plurality of radiation-hardened SRAM cells and the second bi-state node of each of the plurality of radiation-hardened SRAM cells are interleaved.

39. A radiation-hardened SRAM cell in accordance with claim 31 wherein said first circuit comprises:
a low volume well; and
a conductive path comprising low resistance material adjacent to and shielding the low volume well.

40. A radiation-hardened SRAM cell in accordance with claim 31 wherein said second circuit comprises:
a low volume well; and
a conductive path comprising low resistance material adjacent to and shielding the low volume well.

41. A radiation hardened SRAM cell in accordance with claim 31 wherein both the first circuit and the second circuit each comprises:
a low volume well; and
a conductive path comprising low resistance material adjacent to and shielding the low volume well.

42. A radiation-hardened SRAM comprising:
a plurality of interleaved bit cells, each bit cell comprising:
a first bi-state node connected to a bit line via a first selector and a second selector;
a second bi-state node connected to a not bit line via a third selector and a fourth selector;
a first circuit arranged between the first node and the second node configured to maintain the second node in an opposite state of the first node; and
a second circuit arranged between the second node and the first node configured to maintain the first node in an opposite state of the second node.

43. A radiation-hardened SRAM in accordance with claim 42 wherein pairs of adjacent bit cells are interleaved.

44. A radiation-hardened SRAM in accordance with claim 43 wherein the first bi-state node of a first bit cell of the pair is adjacent to the first bi-state node of a second bit cell of the pair.

45. A radiation-hardened SRAM in accordance with claim 43 wherein the second bi-state node of a first bit cell of the pair is adjacent to the second bi-state node of a second bit cell of the pair.

46. A radiation-hardened SRAM in accordance with claim 43 wherein the first bi-state node, the first selector, the second selector and the first circuit of a first bit cell of the pair is adjacent to the first bi-state node, the first selector, the second selector and the first circuit of a second bit cell of the pair.

47. A radiation-hardened SRAM in accordance with claim 43 wherein the second bi-state node, the third selector, the fourth selector and the second circuit of a first bit cell of the pair is adjacent to the second bi-state node, the third selector, the fourth selector and the second circuit of a second bit cell of the pair.

48. A radiation-hardened SRAM in accordance with claim 42 wherein an Nth bit cell is interleaved with an N+X bit cell.
